(19) United States
(12) Patent Application Publication
(10) Pub. No.: US 2026/0031172 A1
(43) Pub. Date: Jan. 29, 2026

(54) CORRECTIVE READ AGGRESSOR INFORMATION FOR ERROR CORRECTION CODE ENHANCEMENT

(71) Applicant: Micron Technology, Inc., Boise, ID (US)

(72) Inventors: Jeffrey Scott MCNEIL, JR., Nampa, ID (US); Sundararajan N. SANKARANARAYANAN, Fremont, CA (US); Xiangyu TANG, San Jose, CA (US)

(21) Appl. No.: 18/939,061

(22) Filed: Nov. 6, 2024

Related U.S. Application Data
(60) Provisional application No. 63/675,444, filed on Jul. 25, 2024.

(51) Int. Cl. G11C 29/42

(52) U.S. Cl. CPC G11C 29/42

(57) ABSTRACT

A memory device includes a memory cell array; and a memory controller configured to determine corrective read information. The memory controller is configured to: perform a hard read on a victim memory cell based on a hard read threshold to estimate a memory state of the victim memory cell, perform one or more soft reads on the victim memory cell to generate soft information for the victim memory cell, calculate an initial error correction confidence value of the victim memory cell based on the hard read and the soft information, perform a hard read on a neighboring aggressor memory cell to determine a memory state of the neighboring aggressor memory cell, and refine the initial error correction confidence value of the victim memory cell, based on the hard read on the neighboring aggressor memory cell, to generate a refined error correction confidence value of the victim memory cell.

### CROSS-REFERENCE TO RELATED APPLICATION

This Patent Application claims priority to U.S. Provisional Patent Application No. 63/675,444, filed on Jul. 25, 2024, entitled “CORRECTIVE READ AGGRESSOR INFORMATION FOR ERROR CORRECTION CODE ENHANCEMENT,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to using corrective read aggressor information for error correction code enhancement.

### BACKGROUND

A non-volatile memory device, such as a NAND memory device, may use circuitry to enable electrically programming, erasing, and storing of data even when a power source is not supplied. Non-volatile memory devices may be used in various types of electronic devices, such as computers, mobile phones, or automobile computing systems, among other examples.

A non-volatile memory device may include an array of memory cells, a page buffer, and a column decoder. In addition, the non-volatile memory device may include a control logic unit (e.g., a controller), a row decoder, or an address buffer, among other examples. The memory cell array may include memory cell strings connected to bit lines, which are extended in a column direction.

A memory cell, which may be referred to as a “cell” or a “data cell,” of a non-volatile memory device may include a current path formed between a source and a drain on a semiconductor substrate. The memory cell may further include a floating gate and a control gate formed between insulating layers on the semiconductor substrate. A programming operation (sometimes called a write operation) of the memory cell is generally accomplished by grounding the source and the drain areas of the memory cell and the semiconductor substrate of a bulk area, and applying a high positive voltage, which may be referred to as a “program voltage,” a “programming power voltage,” or “VPP,” to a control gate to generate Fowler-Nordheim tunneling (referred to as “F-N tunneling”) between a floating gate and the semiconductor substrate. When F-N tunneling is occurring, electrons of the bulk area are accumulated on the floating gate by an electric field of a VPP applied to the control gate to increase a threshold voltage of the memory cell.

An erasing operation of the memory cell is concurrently performed in units of sectors sharing the bulk area (referred to as “blocks”), by applying a high negative voltage, which may be referred to as an “erase voltage” or “Vera,” to the control gate, and a configured voltage to the bulk area to generate the F-N tunneling. In this case, electrons accumulated on the floating gate are discharged into the source area, so that the memory cells have an erasing threshold voltage distribution.

Each memory cell string may have a plurality of floating gate type memory cells serially connected to each other. Access lines (sometimes called “word lines”) are extended in a row direction, and a control gate of each memory cell is connected to a corresponding access line. A non-volatile memory device may include a plurality of page buffers connected between the bit lines and the column decoder. The column decoder is connected between the page buffer and data lines.

### BRIEF DESCRIPTION OF THE DRAWINGS

FIG. 1 is a diagram illustrating an example system capable of using corrective read aggressor information for error correction code enhancement.

FIG. 2 is a diagram illustrating an example of components included in a memory device.

FIG. 3 is a diagram of example components included in the memory device.

FIG. 4 is a diagram illustrating an example of a confidence level scheme that may be used in a non-volatile memory device.

FIG. 5 is a diagram illustrating an example of read errors that may occur in a multi-level cell (MLC) non-volatile memory device.

FIG. 6 is a flowchart of an example method associated with using corrective read aggressor information for error correction code enhancement.

### DETAILED DESCRIPTION

In the realm of data storage, non-volatile memory (NVM) devices, such as NAND flash memories, store information in memory cells. These cells, organized into word lines, can be subject to disturbance when adjacent cells are programmed. This unintentional interference is particularly problematic when reading data stored in a memory cell that has been disturbed, potentially leading to incorrect data retrieval.

Some implementations described herein provide a technical solution for refining the error correction process in non-volatile memory devices. Specifically, a memory controller is technologically enhanced to perform a hard read operation on a victim memory cell using a hard read threshold to estimate the memory state of the victim memory cell. Additionally, the memory controller executes one or more soft reads on the victim memory cell at various soft read thresholds to generate soft information. The memory controller may compute an initial error correction confidence value for the victim memory cell using the obtained hard read result and the soft information. The memory cell may also conduct a hard read on an adjacent aggressor memory cell to ascertain its memory state (e.g., substate) and may utilize the aggressor information to adjust the initial error correction confidence value of the victim memory cell, thereby yielding a refined error correction confidence value.

Thus, the memory controller may consider the memory state of the neighboring aggressor memory cell, which can occupy either a high substate or a low substate, to increase a precision of the error correction confidence value. In this way, the memory controller refines the error correction confidence values for memory cells such that memory errors can be corrected with higher accuracy. The result is the corrected data with significantly reduced error rates. This technical advancement enhances the precision of data retrieval in scenarios susceptible to disturbance effects induced by programming of adjacent memory cells. Moreover, the solution enhances the reliability of data storage and retrieval, particularly in NAND technologies where voltage distributions of threshold voltages are narrowly spaced. By leveraging the refined error correction confidence values, the solution potentially minimizes the necessity for repeated read operations and reduces wear on the memory cells, therefore conserving energy and prolonging the life span of the memory device. It also enhances the performance of error correction protocols, which can lead to the conservation of processing resources and memory resources in a larger data storage and retrieval ecosystem.

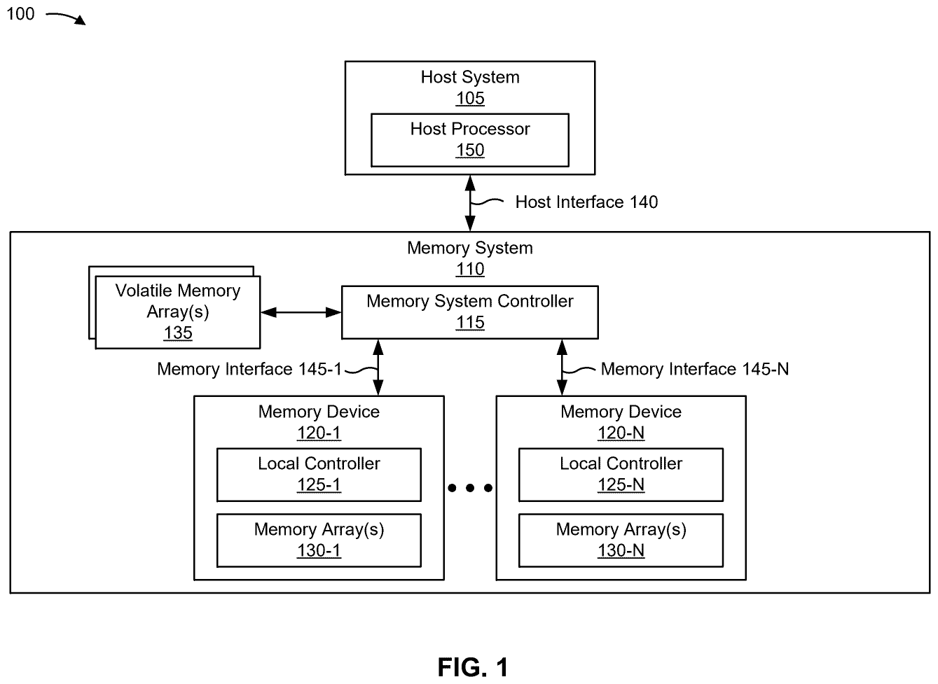

FIG. 1 is a diagram illustrating an example system 100 capable of using corrective read aggressor information for error correction code enhancement. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130 (e.g., memory cell arrays). The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IOT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller.

Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

The controller (e.g., the memory system controller 115 or a local controller 125) may perform error detection, corrective read operations (e.g., look ahead reads), and error correction based on the error detection and corrective read operations. For example, the controller may use error correction codes (ECCs) for error detection and error correction. In addition, the controller (e.g., the memory system controller 115 or a local controller 125) may include an ECC decoder configured to detect errors based on redundancy bits and a decoding algorithm, receive corrective read information generated by the corrective read operations, and correct errors based on the corrective read information. The ECC decoder may use an error correction coding scheme, such as Low-Density Parity-Check (LDPC) codes. Thus, the EEC decoder may be an LDPC decoder. The ECC decoder may be integrated into the controller, or may be provided separately from the controller.

In some implementations, one or more systems, devices, apparatuses, components, and/or controllers of FIG. 1 may include a memory comprising a memory cell array arranged according to a plurality of word lines and a plurality of bit lines; and a memory controller configured to manage operations of the memory to determine corrective read information, wherein the memory controller is configured to: perform a hard read on a victim memory cell based on a hard read threshold to estimate a memory state of the victim memory cell, perform one or more soft reads on the victim memory cell based on one or more soft read thresholds to generate soft information for the victim memory cell, calculate an initial error correction confidence value of the victim memory cell based on the hard read performed on the victim memory cell and the soft information, perform a hard read on a neighboring aggressor memory cell to determine a memory state of the neighboring aggressor memory cell, the memory state of the neighboring aggressor memory cell being in a high substate or a low substate, and refine the initial error correction confidence value of the victim memory cell, based on the hard read on the neighboring aggressor memory cell and based on a vector of the initial error correction confidence value, to generate a refined error correction confidence value of the victim memory cell.

In some implementations, one or more systems, devices, apparatuses, components, and/or controllers of FIG. 1 may include a memory comprising a memory cell array arranged according to a plurality of word lines and a plurality of bit lines; and a memory controller configured to manage corrective read operations of the memory, wherein the memory controller is configured to: perform a hard read on a victim memory cell based on a hard read threshold to estimate a memory state of the victim memory cell, perform one or more soft reads on the victim memory cell based on one or more soft read thresholds to generate soft information for the victim memory cell, calculate an initial log likelihood ratio (LLR) value of the victim memory cell based on the hard read performed on the victim memory cell and the soft information, perform a hard read on a neighboring aggressor memory cell to determine a memory state of the neighboring aggressor memory cell, the memory state of the neighboring aggressor memory cell being in a high substate or a low substate, and refine the initial LLR value of the victim memory cell, based on the hard read on the neighboring aggressor memory cell and based on an LLR value bucket of the initial LLR value, to generate a refined LLR value of the victim memory cell, wherein the high substate is a high-voltage state corresponding to a programmed state of the neighboring aggressor memory cell, and wherein the low substate is a low-voltage state corresponding to an erased state of the neighboring aggressor memory cell.

In some implementations, one or more systems, devices, apparatuses, components, and/or controllers of FIG. 1 may be configured to perform a hard read on the victim memory cell based on a hard read threshold to estimate a memory state of the victim memory cell; perform one or more soft reads on the victim memory cell based on one or more soft read thresholds to generate soft information for the victim memory cell; calculate an initial error correction confidence value of the victim memory cell based on the hard read performed on the victim memory cell and the soft information; perform a hard read on a neighboring aggressor memory cell to determine a memory state of the neighboring aggressor memory cell, the memory state of the neighboring aggressor memory cell being in a high substate or a low substate; and the initial error correction confidence value of the victim memory cell, based on the hard read on the neighboring aggressor memory cell and based on a vector of the initial error correction confidence value, to generate a refined error correction confidence value of the victim memory cell.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

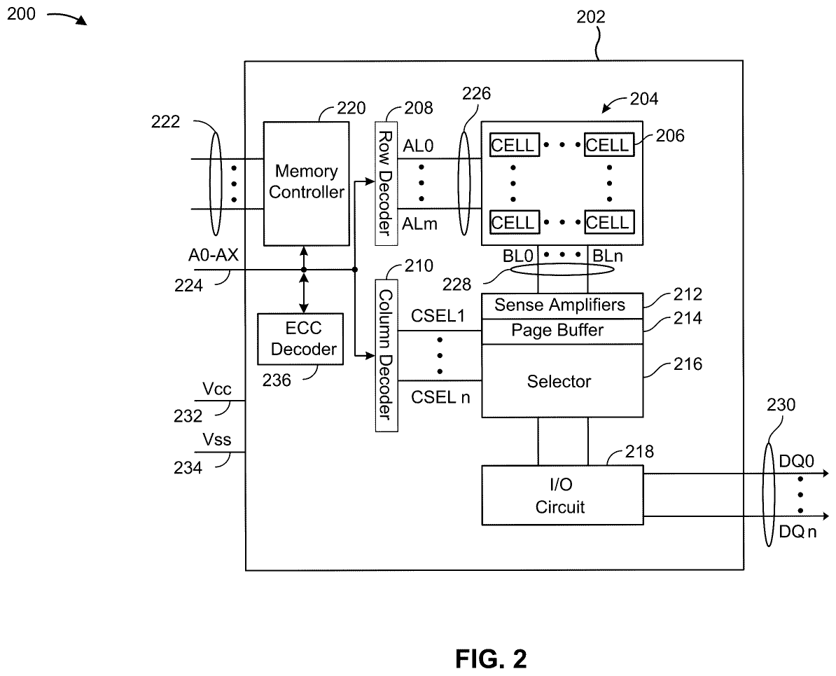

FIG. 2 is a diagram illustrating an example 200 of components included in a memory device 202. The memory device 202 may be the memory system 110. The memory device 202 may include a memory array 204 having multiple memory cells 206. The memory device 202 may include one or more components (e.g., circuits) to transmit signals to or perform memory operations on the memory array 204. For example, the memory device 202 may include a row decoder 208, a column decoder 210, one or more sense amplifiers 212, a page buffer 214, a selector 216, an input/output (I/O) circuit 218, and a memory controller 220. The memory controller 220 may be the memory system controller 115 or a local controller 125.

The memory controller 220 may control memory operations of the memory device 202 according to one or more signals received via one or more control lines 222, such as one or more clock signals or control signals that indicate an operation (e.g., write, read, or erase) to be performed. Additionally, or alternatively, the memory controller 220 may determine one or memory cells 206 upon which the operation is to be performed based on one or more signals received via one or more address lines 224, such as one or more address signals (shown as A0-AX). A host device external from the memory device 202 may control the values of the control signals on the control lines 222 and/or the address signals on the address line 224.

The memory device 202 may use access lines 226 (sometimes called word lines or row lines, and shown as AL0-ALm) and bit lines 228 (sometimes called digit lines or column lines, and shown as BL0-BLn) to transfer data to or from one or more of the memory cells 206. For example, the row decoder 208 and the column decoder 210 may receive and decode the address signals (A0-AX) from the address line 224 and may determine which of the memory cells 206 are to be accessed based on the address signals. The row decoder 208 and the column decoder 210 may provide signals to those memory cells 206 via one or more access lines 226 and one or more bit lines 228, respectively.

For example, the column decoder 210 may receive and decode address signals into one or more column select signals (shown as CSEL1-CSELn). The selector 216 may receive the column select signals and may select data in the page buffer 214 that represents values of data to be read from or to be programmed into memory cells 206. The page buffer 214 may be configured to store data received from a host device before the data is programmed into relevant portions of the memory array 204, or the page buffer 214 may store data read from the memory array 204 before the data is transmitted to the host device. The sense amplifiers 212 may be configured to determine the values to be read from or written to the memory cells 206 using the bit lines 228. For example, in a selected string of memory cells 206, a sense amplifier 212 may read a logic level in a memory cell 206 in response to a read current flowing through the selected string to a bit line 228. The I/O circuit 218 may transfer values of data into or out of the memory device 202 (e.g., to or from a host device), such as into or out of the page buffer 214 or the memory array 204, using I/O lines 230 (shown as (DQ0-DQn)).

The memory controller 220 may generate or receive positive and negative supply signals, such as a supply voltage (Vcc) 232 and a negative supply (Vss) 234 (e.g., a ground potential), from an external source or power supply (e.g., an internal battery, an external battery, and/or an AC-to-DC converter).

The memory device 202 may include an ECC decoder 236 configured to detect and correct errors (e.g., bit errors) based on an ECC algorithm. The ECC decoder 236 may be communicatively coupled to the memory controller 220 or may be integrated in the memory controller 220. The memory controller 220 may perform corrective read operations to generate corrective read information, and provide the corrective read information to the ECC decoder 236. The ECC decoder 236 may use the corrective read information to correct errors. For example, the corrective read information may include an error correction confidence value, such as a log likelihood ratio (LLR) value. The ECC decoder 236 may determine a most probable value for a memory value (e.g., a bit value) of a memory cell based on the error correction confidence value for that memory cell, thus correcting an error that may be associated with the memory cell. Corrective reads may provide additional data points for more accurate error correction. For example, LLRs may offer a probabilistic measure of bit reliability that is used for iterative decoding algorithms, such as LDPC.

In some cases, errors may be caused by cell-to-cell interference. For example, in NAND flash memory, memory cells are arranged in close proximity, and programming or reading one memory cell can affect one or more neighboring memory cells. This phenomenon is known as cell-to-cell interference. An aggressor memory cell is a memory cell whose state (voltage level) can influence the state of an adjacent “victim” memory cell, causing errors. Thus, the victim memory cell and a neighboring aggressor memory cell may be arranged on adjacent word lines of the memory array 204. As a result, the victim memory cell and the neighboring aggressor memory cell may be referred to as adjacent memory cells.

The memory controller 220 may use an aggressor read technique to refine corrective read information, such as the error correction confidence value, of a victim memory cell. The memory controller 220 may read the victim memory cell multiple times while considering different possible states of an aggressor memory cell. The memory controller 220 may refine or adjust the error correction confidence value of the victim memory cell based on a state of the aggressor memory cell. The ECC decoder 236 may use the error correction confidence value in an iterative process to refine and correct the data of the victim memory cell, accounting for the influence of the aggressor memory cell.

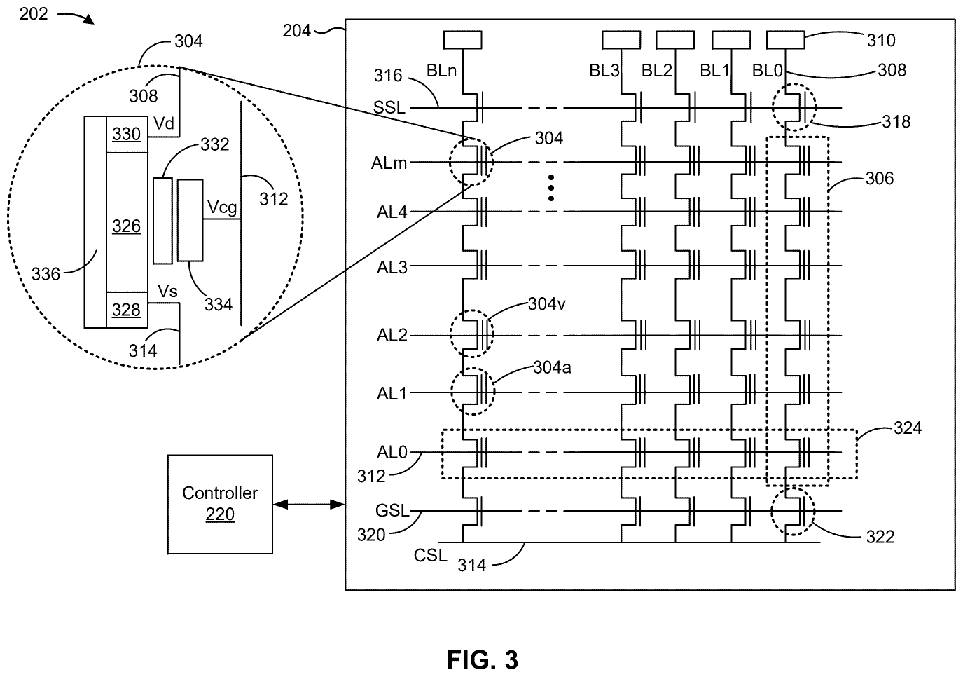

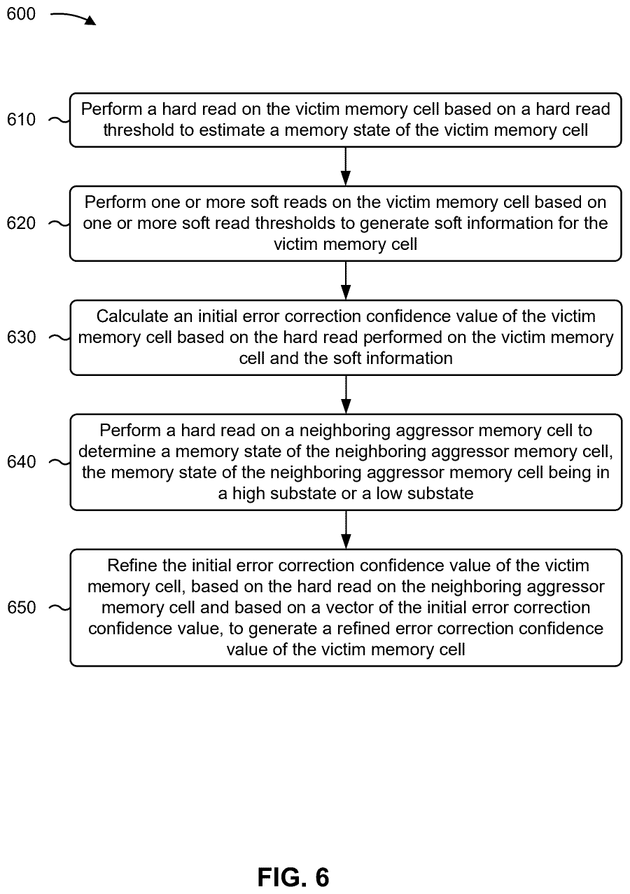

One or more devices or components shown in FIG. 2 may be used to carry out operations described elsewhere herein, such as one or more operations of FIGS. 1 and 3 and/or one or more process blocks of the method of FIGS. 6.

As indicated above, FIG. 2 is provided as an example. Other examples may differ from what is described with regard to FIG. 2.

FIG. 3 is a diagram of example components included in the memory device 202. As described above in connection with FIG. 2, the memory device 202 may include memory controller 220 and memory array 204. The memory controller 220 may include an ECC decoder, such as ECC decoder 236, integrated into the memory controller 220.

In FIG. 3, the memory array 204 is a NAND memory array. However, in some implementations, the memory array 204 may be another type of memory array, such as a NOR memory array, a resistive RAM (RRAM) memory array, a magnetoresistive RAM (MRAM) memory array, a ferroelectric RAM (FeRAM) memory array, a spin-transfer torque RAM (STT-RAM) memory array, or the like. In some implementations, the memory array 204 is part of a three-dimensional stack of memory arrays, such as 3D NAND flash memory, 3D NOR flash memory, or the like.

The memory array 204 includes multiple memory cells 304. A memory cell 304 may store an analog value, such as an electrical voltage or an electrical charge, that represents a data state (e.g., a digital value). The analog value and corresponding data state depend on a quantity of electrons trapped or present within a region of the memory cell 304 (e.g., in a charge trap, such as a floating gate), as described below.

A NAND string 306 (sometimes called a string) may include multiple memory cells 304 connected in series. A NAND string 306 is coupled to a bit line 308 (sometimes called a digit line or a column line, and shown as BL0-BLn). Data can be read from or written to the memory cells 304 of a NAND string 306 via a corresponding bit line 308 using one or more input/output (I/O) components 310 (e.g., an I/O circuit, an I/O bus, a page buffer, and/or a sensing component, such as a sense amplifier). Memory cells 304 of different NAND strings 306 (e.g., one memory cell 304 per NAND string 306) may be coupled with one another via access lines 312 (sometimes called word lines or row lines, and shown as AL0-ALm) that select which row (or rows) of memory cells 304 is affected by a memory operation (e.g., a read operation or a write operation).

A NAND string 306 may be connected to a bit line 308 at one end and a common source line (CSL) 314 at the other end. A string select line (SSL) 316 may be used to control respective string select transistors 318. A string select transistor 318 selectively couples a NAND string 306 to a corresponding bit line 308. A ground select line (GSL) 320 may be used to control respective ground select transistors 322. A ground select transistor 322 selectively couples a NAND string 306 to the common source line 314.

A “page” of memory (or “a memory page”) may refer to a group of memory cells 304 connected to the same access line 312, as shown by reference number 324. In some implementations (e.g., for single-level cells), the memory cells 304 connected to an access line 312 may be associated with a single page of memory. In some implementations (e.g., for multi-level cells), the memory cells 304 connected to an access line 312 may be associated with multiple pages of memory, where each page represents one bit stored in each of the memory cells 304 (e.g., a lower page that represents a first bit stored in each memory cell 304 and an upper page that represents a second bit stored in each memory cell 304). In NAND memory, a page is the smallest physically addressable data unit for a write operation (sometimes called a program operation).

In some implementations, a memory cell 304 is a floating-gate transistor memory cell. In this case, the memory cell 304 may include a channel 326, a source region 328, a drain region 330, a floating gate 332, and a control gate 334. The source region 328, the drain region 330, and the channel 326 may be on a substrate 336 (e.g., a semiconductor substrate). The memory device 120 may store a data state in the memory cell 304 by charging the floating gate 332 to a particular voltage associated with the data state and/or to a voltage that is within a range of voltages associated with the data state. This results in a predefined amount of current flowing through the channel 326 (e.g., from the source region 328 to the drain region 330) when a specified read voltage is applied to the control gate 334 (e.g., by a corresponding access line 312 connected to the control gate 334). Although not shown, a tunnel oxide layer (or tunnel dielectric layer) may be interposed between the floating gate 332 and the channel 326, and a gate oxide layer (e.g., a gate dielectric layer) may be interposed between the floating gate 332 and the control gate 334. As shown, a drain voltage Vd may be supplied from a bit line 308, a control gate voltage Veg may be supplied from an access line 312, and a source voltage Vs may be supplied via the common source line 314 (which, in some implementations, is a ground voltage).

To write or program the memory cell 304, Fowler-Nordheim tunneling may be used. For example, a strong positive voltage potential may be created between the control gate 334 and the channel 326 (e.g., by applying a large positive voltage to the control gate 334 via a corresponding access line 312) while current is flowing through the channel 326 (e.g., from the common source line 314 to the bit line 308, or vice versa). The strong positive voltage at the control gate 334 causes electrons within the channel 326 to tunnel through the tunnel oxide layer and be trapped in the floating gate 332. These negatively charged electrons then act as an electron barrier between the control gate 334 and the channel 326 that increases the threshold voltage of the memory cell 304. The threshold voltage is a voltage required at the control gate 334 to cause current (e.g., a threshold amount of current) to flow through the channel 326. Fowler-Nordheim tunneling is an example technique for storing a charge in the floating gate, and other techniques, such as channel hot electron injection, may be used.

To read the memory cell 304, a read voltage may be applied to the control gate 334 (e.g., via a corresponding access line 312), and an I/O component 310 (e.g., a sense amplifier) may determine the data state of the memory cell 304 based on whether current passes through the memory cell 304 (e.g., the channel 326) due to the applied voltage. A pass voltage may be applied to all memory cells 304 (other than the memory cell 304 being read) in the same NAND string 306 as the memory cell 304 being read. For example, the pass voltage may be applied on each access line 312 other than the access line 312 of the memory cell 304 being read (e.g., where the read voltage is applied). The pass voltage is higher than the highest read voltage associated with any memory cell data states so that all of the other memory cells 304 in the NAND string 306 conduct, and the I/O component 310 can detect a data state of the memory cell 304 being read by sensing current (or lack thereof) on a corresponding bit line 308. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 334 to distinguish between the three or more data states and determine a data state of the memory cell 304. Thus, the memory cells 304 may be single-bit (single-level) memory cells or multi-bit (multi-level) memory cells.

To erase the memory cell 304, a strong negative voltage potential may be created between the control gate 334 and the channel 326 (e.g., by applying a large negative voltage to the control gate 334 via a corresponding access line 312). The strong negative voltage at the control gate 334 causes trapped electrons in the floating gate 332 to tunnel back across the oxide layer from the floating gate 332 to the channel 326 and to flow between the common source line 314 and the bit line 308. This removes the electron barrier between the control gate 334 and the channel 326 and decreases the threshold voltage of the memory cell 304 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block and/or a subset of memory cells of the block.

In FIG. 3, memory cell 304v may be a victim memory cell and memory cell 304a may be a neighboring aggressor memory cell. The memory controller 220 may manage operations of the memory array 204 to determine corrective read information. For example, the memory controller 220 may perform a hard read on the victim memory cell 304v based on a hard read threshold to estimate a memory state of the victim memory cell 304v. The hard read threshold may represent a voltage between threshold voltage distributions associated with two memory states (e.g., threshold voltage distributions associated with binary 0 and 1). Thus, the memory controller 220 may determine whether the victim memory cell 304v is storing a voltage level that is greater than the hard read threshold (e.g., the victim memory cell 304v is in a high-substate) or is less than the hard read threshold (e.g., the victim memory cell 304v is in a low-substate).

In addition, the memory controller 220 may perform one or more soft reads on the victim memory cell 304v based on one or more soft read thresholds to generate soft information for the victim memory cell 304v. For example, the memory controller 220 may adjust the read threshold such that a first soft read threshold is less than the hard read threshold, and perform a read of the voltage level of the victim memory cell 304v based on the first soft read threshold. The memory controller 220 may determine whether the victim memory cell 304v is storing a voltage level that is greater than the first soft read threshold or is less than the first soft read threshold to obtain soft read information associated with the memory state of the victim memory cell 304v. When the voltage level is greater than the first soft read threshold, the memory controller 220 may determine that the voltage level is between the first soft read threshold and the hard read threshold. The memory controller 220 may perform additional soft reads by adjusting the read threshold over a range of threshold values.

Furthermore, the memory controller 220 may adjust the read threshold such that a second soft read threshold is greater than the hard read threshold, and perform a read of the voltage level of the victim memory cell 304v based on the second soft read threshold. The memory controller 220 may determine whether the victim memory cell 304v is storing a voltage level that is greater than the second soft read threshold or is less than the second soft read threshold to obtain soft read information associated with the memory state of the victim memory cell 304v. When the voltage level is less than the second soft read threshold, the memory controller 220 may determine that the voltage level is between the second soft read threshold and the hard read threshold.

Each soft read may be used by the memory controller 220 to generate the soft information. Thus, by adjusting the read thresholds and performing multiple reads, the memory controller 220 may better distinguish between the different memory states of the victim memory cell 304v. The memory controller 220 may calculate an initial error correction confidence value of the victim memory cell 304v based on the hard read performed on the victim memory cell 304v and the soft information. The memory controller 220 may calculate an initial LLR value based on the initial error correction confidence value. In some implementations, the initial error correction confidence value may be an LLR value. An LLR value of a bit may be defined as a logarithm of a ratio of probabilities that the bit is a 0 and that the bit is a 1. Thus, the LLR value is a likelihood of different bit states and may be represented as an LLR value bucket. In some implementations, a large positive LLR value may indicate a high confidence that the bit is 0, a large negative LLR value may indicate a high confidence that the bit is 1, and an LLR value that is close to zero may indicate uncertainty about the bit's value. For example, a small positive LLR value may indicate a low confidence that the bit is 0, and a small negative LLR value may indicate a low confidence that the bit is 1. Thus, an error correction confidence value (e.g., an LLR value) may be a vector having both a magnitude and a sign.

The memory controller 220 may perform a hard read on the neighboring aggressor memory cell 304a to determine a memory state of the neighboring aggressor memory cell 304a. The memory state of the neighboring aggressor memory cell 304a may be considered to be in a high substate when a read voltage value of the neighboring aggressor memory cell 304a is greater than the hard read threshold, and may be considered to be in a low substate when the read voltage value of the neighboring aggressor memory cell 304a is less than the hard read threshold.

The memory controller 220 may refine the initial error correction confidence value of the victim memory cell 304v, based on the hard read on the neighboring aggressor memory cell 304a (e.g., based on whether the neighboring aggressor memory cell 304a is in the high substate or the low substate) and based on a vector of the initial error correction confidence value, to generate a refined error correction confidence value of the victim memory cell 304v. Thus, the memory controller 220 may analyze shifts in a read voltage distribution of the victim memory cell 304v influenced by electric fields from the neighboring aggressor memory cell 304a to refine the initial error correction confidence value and generate the refined error correction confidence value. In some implementations, the memory controller 220 may bucketize one or more bits of the victim memory cell 304v into different confidence levels (or buckets) based on a substate of the neighboring aggressor memory cell 304a. The memory controller 220 may selectively modify an initial LLR value of the victim memory cell 304v based on the refined error correction confidence value. In some implementations, the refined error correction confidence value may be a refined LLR value.

The memory controller 220 may, based on the memory state of the neighboring aggressor memory cell 304a being in the low substate, refine the initial error correction confidence value, the vector of which indicates a low confidence of an erased state, by adjusting the initial error correction confidence value to a lower confidence level. For example, the initial error correction confidence value may be decreased toward zero, from a more positive value to a less positive value. Thus, the memory controller 220 may decrease the magnitude of the initial error correction. The memory controller 220 may, based on the memory state of the neighboring aggressor memory cell 304a being in the high substate, refine the initial error correction confidence value, the vector of which indicates a low confidence of a programmed state, by adjusting the initial error correction confidence value to a lower confidence level. For example, the initial error correction confidence value may be increased toward zero, from a more negative value to a less negative value. Thus, the memory controller 220 may decrease the magnitude of the initial error correction.

The erased state may correspond to a bit value of 0, and the programmed state may correspond to a bit value of 1. The vector that indicates the low confidence of the erased state may correspond to the victim memory cell 304v having a first read voltage value that is between the hard read threshold and the first soft read threshold, the first soft read threshold being less than the hard read threshold. Additionally, the vector that indicates the low confidence of the programmed state may correspond to the victim memory cell 304v having a second read voltage value that is between the hard read threshold and a second soft read threshold, the second soft read threshold being greater than the hard read threshold.

In some implementations, the initial error correction confidence value may be an initial LLR value. The memory controller 220 may, based on the memory state of the neighboring aggressor memory cell 304a being in the low substate, refine the initial LLR value, having a vector of +1, by lowering the initial LLR value to zero. The memory controller 220 may, based on the memory state of the neighboring aggressor memory cell 304a being in the high substate, refine the initial LLR value, having a vector of −1, by increasing the initial LLR value to zero. The memory controller 220 may, based on the memory state of the neighboring aggressor memory cell 304a being in the low substate, refine the initial LLR value, having a vector of +2, by lowering the initial LLR value to +1 or to zero. The memory controller 220 may, based on the memory state of the neighboring aggressor memory cell 304a being in the high substate, refine the initial LLR value, having a vector of −2, by increasing the initial LLR value to −1 or to zero.

The memory controller 220 may, based on the memory state of the neighboring aggressor memory cell 304a being in the low substate, refine the initial error correction confidence value, the vector of which indicates a low confidence of a programmed state, by adjusting the initial error correction confidence value to a higher confidence level. For example, the memory controller 220 may increase the magnitude of the initial error correction. The memory controller 220 may, based on the memory state of the neighboring aggressor memory cell 304a being in the high substate, refine the initial error correction confidence value, the vector of which indicates a low confidence of an erased state, by adjusting the initial error correction confidence value to a higher confidence level. For example, the memory controller 220 may increase the magnitude of the initial error correction.

The memory controller 220 may, based on the memory state of the neighboring aggressor memory cell 304a being in the high substate, refine the initial error correction confidence value, the vector of which indicates a high confidence of an erased state, by adjusting the initial error correction confidence value to a higher confidence level. The memory controller 220 may, based on the memory state of the neighboring aggressor memory cell 304a being in the low substate, refine the initial error correction confidence value, the vector of which indicates a high confidence of a programmed state, by adjusting the initial error correction confidence value to a higher confidence level. The vector that indicates the high confidence of the erased state may correspond to the victim memory cell 304v having a first read voltage value that is less than a first soft read threshold, the first soft read threshold being less than the hard read threshold. The vector that indicates the high confidence of the programmed state may correspond to the victim memory cell 304v having a second read voltage value that is greater than a second soft read threshold, the second soft read threshold being greater than the hard read threshold.

The memory controller 220 may, based on the memory state of the neighboring aggressor memory cell 304a being in the high substate, refine the initial error correction confidence value, the vector of which indicates a high confidence of an erased state, by maintaining the initial error correction confidence value at a same confidence level. For example, the initial error correction confidence value may already be at a maximum confidence level of the erased state, or the soft information may not be strong enough to adjust the initial error correction confidence value. The memory controller 220 may, based on the memory state of the neighboring aggressor memory cell 304a being in the low substate, refine the initial error correction confidence value, the vector of which indicates a high confidence of a programmed state, by maintaining the initial error correction confidence value at a same confidence level. For example, the initial error correction confidence value may already be at a maximum confidence level for the programmed state, or the soft information may not be strong enough to adjust the initial error correction confidence value.

The memory controller 220 may, based on the memory state of the neighboring aggressor memory cell 304a being in the high substate, refine the initial error correction confidence value, the vector of which indicates a high confidence of a programmed state, by adjusting the initial error correction confidence value to a lower confidence level. The memory controller 220 may, based on the memory state of the neighboring aggressor memory cell 304a being in the low substate, refine the initial error correction confidence value, the vector of which indicates a high confidence of an erased state, by adjusting the initial error correction confidence value to a lower confidence level.

The memory controller 220 (e.g., the ECC decoder) may receive the refined error correction confidence value, and determine a memory value of the victim memory cell 304v based on the refined error correction confidence value. The ECC decoder may correct individual bits of single-bit memory cells or multi-bit memory cells.

As indicated above, FIG. 3 is provided as an example. Other examples may differ from what is described with regard to FIG. 3.

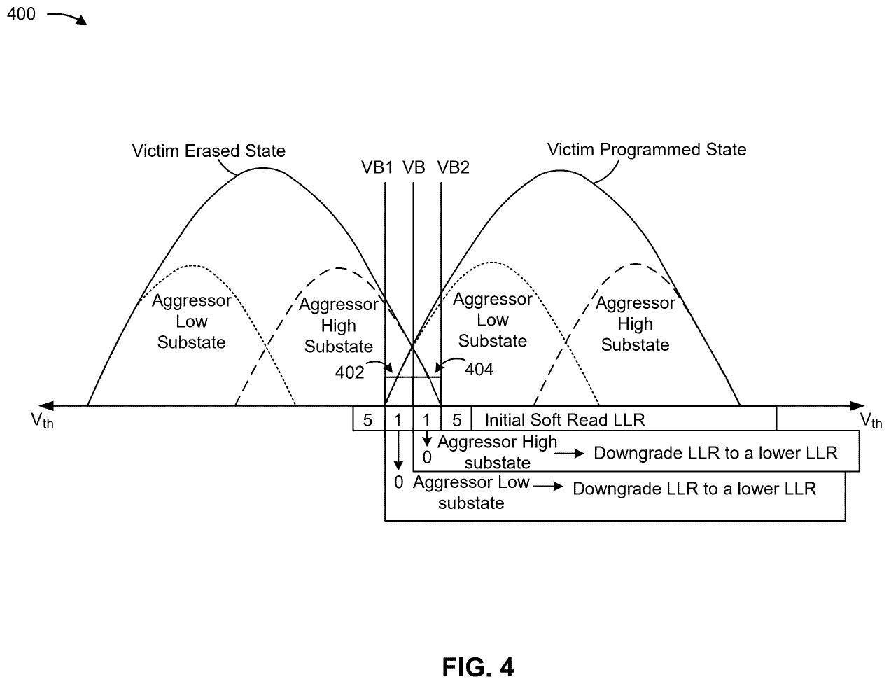

FIG. 4 is a diagram illustrating an example 400 of a confidence level scheme that may be used in a non-volatile memory device. A hard read threshold VB may represent a voltage between threshold voltage distributions associated with two memory states (e.g., threshold voltage distributions associated with binary 0 and 1). A first soft read threshold VB1 may represent a voltage that is less than the hard read threshold VB. A second soft read threshold VB2 may represent a voltage that is greater than the hard read threshold VB.

If current flows when VB is applied to a memory cell, then the threshold voltage of the memory cell may be considered to be less than VB, thus corresponding to binary 1. If current does not flow when VB is applied to the memory cell, then the threshold voltage may be considered to be more than VB, thus corresponding to binary 0.

If current flows when VB1 is applied to a memory cell, then the threshold voltage of the memory cell may be considered to be less than VB1, thus corresponding to a lower confidence of binary 0 or to a binary 1. If current does not flow when VB1 is applied to the memory cell, then the threshold voltage may be considered to be more than VB1, thus corresponding to a higher confidence of binary 0. A region between VB1 and VB may be a soft region 402 of the erased state (e.g., of binary 0) in which the memory state of the memory cell is uncertain due to shift in voltage level of the memory cell, which may be caused by cell-to-cell interference. For example, an LLR value of a memory cell may be assigned a magnitude of 1 when a voltage level of the memory cell is determined to be in the soft region 402, and may be a higher value (e.g., 5) when the voltage level of the memory cell is determined to be less than VB1.

If current flows when VB2 is applied to a memory cell, then the threshold voltage of the memory cell may be considered to be less than VB2, thus corresponding to a higher confidence of binary 1. If current does not flow when VB2 is applied to the memory cell, then the threshold voltage may be considered to be more than VB2, thus corresponding to a lower confidence of binary 1 or to a binary 0. A region between VB and VB2 may be a soft region 404 of the programmed state (e.g., of binary 1) in which the memory state of the memory cell is uncertain due to a shift in voltage level of the memory cell, which may be caused by cell-to-cell interference. For example, an LLR value of a memory cell may be assigned a magnitude of 1 when a voltage level of the memory cell is determined to be in the soft region 404, and may be a higher value (e.g., 5) when the voltage level of the memory cell is determined to be greater than VB2.

In an example in which the soft information of the victim memory cell indicates that the voltage level of the victim memory cell is in the soft region 402 (e.g., initial LLR value=+1), and the memory controller 220 determines that the memory state of the neighboring aggressor memory cell is in the low substate, the memory controller 220 may downgrade the initial LLR of the victim memory cell to a lower LLR, such as 0.

In an example in which the soft information of the victim memory cell indicates that the voltage level of the victim memory cell is in the soft region 404 (e.g., initial LLR value=−1), and the memory controller 220 determines that the memory state of the neighboring aggressor memory cell is in the high substate, the memory controller 220 may downgrade the initial LLR of the victim memory cell to a lower LLR, such as 0.

Thus, the memory controller 220 may bucketize a bit of the victim memory cell into different confidence levels based on a substate of the neighboring aggressor memory cell. The memory controller 220 may refine an initial LLR value based on an LLR value bucket of the initial LLR value. The LLR value bucket may indicate an initial confidence level (e.g., a low confidence level or a high confidence level). The substate of the neighboring aggressor memory cell may be evaluated to further categorize and refine the initial LLR value that was determined based on the hard read performed on the victim memory cell and the soft information. The memory controller 220 may increase or decrease an initial error correction confidence level based on the substate of the neighboring aggressor memory cell, as described in connection with FIGS. 1-3.

As indicated above, FIG. 4 is provided as an example. Other examples may differ from what is described with regard to FIG. 4.

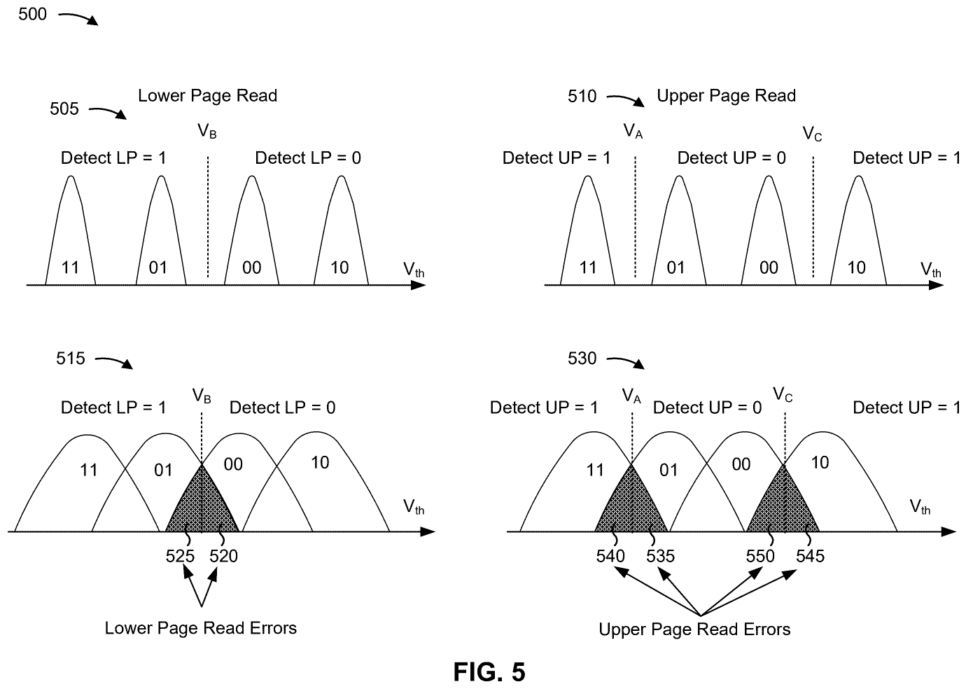

FIG. 5 is a diagram illustrating an example 500 of read errors that may occur in an MLC non-volatile memory device. Although the read errors described in connection with FIG. 5 are described in the context of an MLC, the described concepts also apply to other types of memory cells, such as single-level cells (SLCs), triple-level cells (TLCs), quad-level cells (QLCs), and other types of memory cells.

Some memory devices may be capable of storing multiple bits per memory cell. For example, an MLC non-volatile memory device (e.g., an MLC flash device) may be capable of storing two bits of information per memory cell in one of four states (e.g., may store binary 11, binary 01, binary 00, or binary 10 depending on a charge applied to the memory cell). To read the data of a memory cell, such as the MLC shown in FIG. 5, the memory device (or a component thereof) may apply a read reference voltage to the cell in an effort to induce current in the memory cell, and the memory device (or a component thereof) may determine a corresponding bit string associated with a voltage that induced (or else did not induce) current. Put another way, the memory device may apply various read reference voltages to sense the threshold voltage (Vth) associated with the data stored in the cell.

More particularly, for an MLC, the memory device may perform a lower page (also shown as LP) read and an upper page (also shown as UP) read. As shown by reference number 505, for a lower page read, the memory device may apply to a read reference voltage, shown as VB. VB may represent a voltage between threshold voltage distributions associated with the first two states (e.g., threshold voltage distributions associated with binary 11 and 01) and threshold voltage distributions associated with the second two states (e.g., threshold voltage distributions associated with binary 00 and 10). If current flows when VB is applied to the memory cell, then the threshold voltage may be considered to be less than VB, thus corresponding to one of binary 11 or binary 01 (meaning that the lower page data represents a “1”). If current does not flow when VB is applied to the memory cell, then the threshold voltage may be considered to be more than VB, thus corresponding to one of binary 00 or binary 10 (meaning that the lower page data represents a “0”).

As shown by reference number 510, an upper page read may be performed in a similar manner. More particularly, when the detected lower page data is a “1”, a read reference voltage of VA may be applied to the memory cell to thereafter determine the upper page data. VA may represent a voltage between a threshold voltage distribution associated with the first state (e.g., a threshold voltage distribution associated with binary 11) and a threshold voltage distribution associated with the second state (e.g., a threshold voltage distribution associated with binary 01). If current flows when VA is applied to the memory cell, then the threshold voltage may be considered to be less than VA, thus corresponding to binary 11 (meaning that the upper page data represents a “1”). If current does not flow when VA is applied to the memory cell, then the threshold voltage may be considered to be more than VA but less than VB (as determined during the lower page read), thus corresponding to binary 01 (meaning that the upper page data represents a “0”).

Similarly, when the detected lower page data is a “0,” a read reference voltage of VC may be applied to the memory cell to thereafter determine the upper page data. VC may represent a voltage between a threshold voltage distribution associated with the third state (e.g., a threshold voltage distribution associated with binary 00) and a threshold voltage distribution associated with the fourth state (e.g., a threshold voltage distribution associated with binary 10). If current flows when VC is applied to the memory cell, then the threshold voltage may be considered to be less than VC but more than VB (as determined during the lower page read), thus corresponding to binary 00 (meaning that the upper page data represents a “0”). If current does not flow when VC is applied to the memory cell, then the threshold voltage may be considered to be more than VC, thus corresponding to binary 10 (meaning that the upper page data represents a “1”).

In some cases, the threshold voltage distributions shown in FIG. 5 may be broadened due to noise or the like, which may lead to read errors at the memory device. Noise in the memory cell may be caused by various sources, such as program-erase (P/E) cycling stress, charge leakage over time, read disturbances (e.g., disturbances caused by the application of a high voltage to a memory cell of a page not being read to deselect the cell while other cells on the page are being read), programming errors, cell-to-cell interference (such as unintentional electrical disturbance and/or interference of a memory cell when neighboring cells are read, written, or erased), or the like. As shown in FIG. 5, broadened voltage threshold distributions may lead to read errors, such as lower page read errors and/or upper page read errors.

First, as shown by reference number 515, a lower page read error may be caused by the broadening of voltage distributions that are near VB and/or that overlap with VB. In the example shown in FIG. 5, the threshold voltage distributions associated with binary 01 and binary 00 have broadened to overlap with the read reference voltage VB. This may result in a lower page read error because a cell programmed with binary 01 may act in a similar manner to a cell programmed with binary 00 (e.g., in response to an applied voltage). More particularly, if VB is applied to a memory cell that stores binary 01 but that is associated with a threshold voltage in the area labeled with reference number 520, no current would flow, erroneously indicating that the lower page data represents a “0” rather than a “1”. On the other hand, if VB is applied to a memory cell that stores binary 00 but that is associated with a threshold voltage in the area labeled with reference number 525, current would flow, erroneously indicating that the lower page data represents a “1” rather than a “0”.

Similarly, as shown by reference number 530, when performing an upper page read, an upper page read error may be caused by the broadening of voltage distributions that are near VA and/or VC and/or that overlap with VA and/or VC. For example, memory cells storing binary 11 and associated with a threshold voltage in the area labeled by 535 may be erroneously read as storing upper page data of “0”, memory cells storing binary 01 and associated with a threshold voltage in the area labeled by 540 may be erroneously read as storming upper page data of “1”, memory cells storing binary 00 and associated with a threshold voltage in the area labeled by 545 may be erroneously read as storing upper page data of “1”, and memory cells storing binary 10 and associated with a threshold voltage in the area labeled by 550 may be erroneously read as storing upper page data of “0”.

In some cases, a memory device may attempt to adjust one or more read reference voltages in response to one or more of the read errors described above (e.g., in response to a cell storing one logical value or binary number being misread as storing a different logical value or binary number). In some instances, this may be referred to as a read retry or a read recovery process. In a read recovery process, one or more read reference voltages (such as VA, VB, or VC described in connection with the MLC) may be dynamically adjusted to track changes in threshold voltage distributions. More particularly, once a read process fails on a particular page of a memory, the memory device (and, more particularly, the controller and/or a read recovery component thereof) may attempt to recover the page using various read recovery steps, which use shifts in voltages from base read reference voltages. Put another way, the memory device may retry the read of a cell with an adjusted read reference voltage such that read errors are decreased or eliminated.

Returning to the example shown in FIG. 5, if a lower page error resulted in a cell storing binary 00 being read as binary 01, the read reference voltage (VB) may be decreased (e.g., shifted to the left in the diagram shown by reference number 515) in an effort to eliminate the lower page read error. Conversely, if a lower page error resulted in a cell storing binary 01 being read as binary 00, the read reference voltage (VB) may be increased (e.g., shifted to the right in the diagram shown by reference number 515). Similarly, the read reference voltages VA and VC may be shifted left or right (e.g., decreased or increased) in an effort to reduce or eliminate upper page read errors.

The memory controller 220 may analyze shifts in a read voltage distribution of a victim memory cell influenced by electric fields from a neighboring aggressor memory cell, as described in connection with FIGS. 1-4, in order to generate a refined error correction confidence value of the victim memory cell.

As indicated above, FIG. 5 is provided as an example. Other examples may differ from what is described with regard to FIG. 5.

FIG. 6 is a flowchart of an example method 600 associated with using corrective read aggressor information for error correction code enhancement. In some implementations, a memory controller (e.g., the memory controller 220) may perform or may be configured to perform the method 600. In some implementations, another device or a group of devices separate from or including the memory controller (e.g., ECC decoder 236) may perform or may be configured to perform the method 600. Additionally, or alternatively, one or more components of the memory controller (e.g., ECC decoder 236) may perform or may be configured to perform the method 600. Thus, means for performing the method 600 may include the memory controller and/or one or more components of the memory controller. Additionally, or alternatively, a non-transitory computer-readable medium may store one or more instructions that, when executed by the memory controller, cause the memory controller to perform the method 600.

As shown in FIG. 6, the method 600 may include performing a hard read on the victim memory cell based on a hard read threshold to estimate a memory state of the victim memory cell (block 610). As further shown in FIG. 6, the method 600 may include performing one or more soft reads on the victim memory cell based on one or more soft read thresholds to generate soft information for the victim memory cell (block 620). As further shown in FIG. 6, the method 600 may include calculating an initial error correction confidence value of the victim memory cell based on the hard read performed on the victim memory cell and the soft information (block 630). As further shown in FIG. 6, the method 600 may include performing a hard read on a neighboring aggressor memory cell to determine a memory state of the neighboring aggressor memory cell, the memory state of the neighboring aggressor memory cell being in a high substate or a low substate (block 640). As further shown in FIG. 6, the method 600 may include refining the initial error correction confidence value of the victim memory cell, based on the hard read on the neighboring aggressor memory cell and based on a vector of the initial error correction confidence value, to generate a refined error correction confidence value of the victim memory cell (block 650).

The method 600 may include additional aspects, such as any single aspect or any combination of aspects described below and/or described in connection with one or more other methods or operations described elsewhere herein.

In a first aspect, the method 600 includes selectively modifying, by the memory controller, an LLR value of the victim memory cell based on the refined error correction confidence value.

In a second aspect, alone or in combination with the first aspect, the method 600 includes bucketizing, by the memory controller, one or more bits of the victim memory cell into different confidence levels based on a substate of the neighboring aggressor memory cell.

In a third aspect, alone or in combination with one or more of the first and second aspects, the method 600 includes analyzing, by the memory controller, shifts in a read voltage distribution of the victim memory cell influenced by electric fields from the neighboring aggressor memory cell.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory device comprises: a memory comprising a memory cell array arranged according to a plurality of word lines and a plurality of bit lines; and a memory controller configured to manage operations of the memory to determine corrective read information, wherein the memory controller is configured to: perform a hard read on a victim memory cell based on a hard read threshold to estimate a memory state of the victim memory cell, perform one or more soft reads on the victim memory cell based on one or more soft read thresholds to generate soft information for the victim memory cell, calculate an initial error correction confidence value of the victim memory cell based on the hard read performed on the victim memory cell and the soft information, perform a hard read on a neighboring aggressor memory cell to determine a memory state of the neighboring aggressor memory cell, the memory state of the neighboring aggressor memory cell being in a high substate or a low substate, and refine the initial error correction confidence value of the victim memory cell, based on the hard read on the neighboring aggressor memory cell and based on a vector of the initial error correction confidence value, to generate a refined error correction confidence value of the victim memory cell.

In some implementations, a memory system includes a memory comprising a memory cell array arranged according to a plurality of word lines and a plurality of bit lines; and a memory controller configured to manage corrective read operations of the memory, wherein the memory controller is configured to: perform a hard read on a victim memory cell based on a hard read threshold to estimate a memory state of the victim memory cell, perform one or more soft reads on the victim memory cell based on one or more soft read thresholds to generate soft information for the victim memory cell, calculate an initial LLR value of the victim memory cell based on the hard read performed on the victim memory cell and the soft information, perform a hard read on a neighboring aggressor memory cell to determine a memory state of the neighboring aggressor memory cell, the memory state of the neighboring aggressor memory cell being in a high substate or a low substate, and refine the initial LLR value of the victim memory cell, based on the hard read on the neighboring aggressor memory cell and based on an LLR value bucket of the initial LLR value, to generate a refined LLR value of the victim memory cell, wherein the high substate is a high-voltage state corresponding to a programmed state of the neighboring aggressor memory cell, and wherein the low substate is a low-voltage state corresponding to an erased state of the neighboring aggressor memory cell.

In some implementations, a method of performing a corrective read on a victim memory cell includes performing, by a memory controller, a hard read on the victim memory cell based on a hard read threshold to estimate a memory state of the victim memory cell; performing, by the memory controller, one or more soft reads on the victim memory cell based on one or more soft read thresholds to generate soft information for the victim memory cell; calculating, by the memory controller, an initial error correction confidence value of the victim memory cell based on the hard read performed on the victim memory cell and the soft information; performing, by the memory controller, a hard read on a neighboring aggressor memory cell to determine a memory state of the neighboring aggressor memory cell, the memory state of the neighboring aggressor memory cell being in a high substate or a low substate; and refining, by the memory controller, the initial error correction confidence value of the victim memory cell, based on the hard read on the neighboring aggressor memory cell and based on a vector of the initial error correction confidence value, to generate a refined error correction confidence value of the victim memory cell.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same clement (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No clement, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising;
a memory comprising a memory cell array arranged according to a plurality of word lines and a plurality of bit lines; and
a memory controller configured to manage operations of the memory to determine corrective read information, wherein the memory controller is configured to:
perform a hard read on a victim memory cell based on a hard read threshold to estimate a memory state of the victim memory cell,
perform one or more soft reads on the victim memory cell based on one or more soft read thresholds to generate soft information for the victim memory cell,
calculate an initial error correction confidence value of the victim memory cell based on the hard read performed on the victim memory cell and the soft information,
perform a hard read on a neighboring aggressor memory cell to determine a memory state of the neighboring aggressor memory cell, the memory state of the neighboring aggressor memory cell being in a high substate or a low substate, and
refine the initial error correction confidence value of the victim memory cell, based on the hard read on the neighboring aggressor memory cell and based on a vector of the initial error correction confidence value, to generate a refined error correction confidence value of the victim memory cell.

2. The memory device of claim 1, wherein the memory controller is configured to, based on the memory state of the neighboring aggressor memory cell being in the low substate, refine the initial error correction confidence value, the vector of which indicates a low confidence of an erased state, by adjusting the initial error correction confidence value to a lower confidence level, and
wherein the memory controller is configured to, based on the memory state of the neighboring aggressor memory cell being in the high substate, refine the initial error correction confidence value, the vector of which indicates a low confidence of a programmed state, by adjusting the initial error correction confidence value to a lower confidence level.

3. The memory device of claim 2, wherein the vector that indicates the low confidence of the erased state corresponds to the victim memory cell having a first read voltage value that is between the hard read threshold and a first soft read threshold, the first soft read threshold being less than the hard read threshold, and
wherein the vector that indicates the low confidence of the programmed state corresponds to the victim memory cell having a second read voltage value that is between the hard read threshold and a second soft read threshold, the second soft read threshold being greater than the hard read threshold.

4. The memory device of claim 1, wherein the initial error correction confidence value is an initial log likelihood ratio (LLR) value,
wherein the memory controller is configured to, based on the memory state of the neighboring aggressor memory cell being in the low substate, refine the initial LLR value, having a vector of +1, by lowering the initial LLR value to zero, and
wherein the memory controller is configured to, based on the memory state of the neighboring aggressor memory cell being in the high substate, refine the initial LLR value, having a vector of −1, by increasing the initial LLR value to zero.

5. The memory device of claim 1, wherein the initial error correction confidence value is an initial log likelihood ratio (LLR) value,
wherein the memory controller is configured to, based on the memory state of the neighboring aggressor memory cell being in the low substate, refine the initial LLR value, having a vector of +2, by lowering the initial LLR value to +1 or to zero, and
wherein the memory controller is configured to, based on the memory state of the neighboring aggressor memory cell being in the high substate, refine the initial LLR value, having a vector of −2, by increasing the initial LLR value to −1 or to zero.

6. The memory device of claim 1, wherein the memory controller is configured to, based on the memory state of the neighboring aggressor memory cell being in the low substate, refine the initial error correction confidence value, the vector of which indicates a low confidence of a programmed state, by adjusting the initial error correction confidence value to a higher confidence level, and
wherein the memory controller is configured to, based on the memory state of the neighboring aggressor memory cell being in the high substate, refine the initial error correction confidence value, the vector of which indicates a low confidence of an erased state, by adjusting the initial error correction confidence value to a higher confidence level.

7. The memory device of claim 1, wherein the memory controller is configured to, based on the memory state of the neighboring aggressor memory cell being in the high substate, refine the initial error correction confidence value, the vector of which indicates a high confidence of an erased state, by adjusting the initial error correction confidence value to a higher confidence level, and
wherein the memory controller is configured to, based on the memory state of the neighboring aggressor memory cell being in the low substate, refine the initial error correction confidence value, the vector of which indicates a high confidence of a programmed state, by adjusting the initial error correction confidence value to a higher confidence level.

8. The memory device of claim 7, wherein the vector that indicates the high confidence of the erased state corresponds to the victim memory cell having a first read voltage value that is less than a first soft read threshold, the first soft read threshold being less than the hard read threshold, and
wherein the vector that indicates the high confidence of the programmed state corresponds to the victim memory cell having a second read voltage value that is greater than a second soft read threshold, the second soft read threshold being greater than the hard read threshold.

9. The memory device of claim 1, wherein the memory controller is configured to, based on the memory state of the neighboring aggressor memory cell being in the high substate, refine the initial error correction confidence value, the vector of which indicates a high confidence of an erased state, by maintaining the initial error correction confidence value at a same confidence level, and
wherein the memory controller is configured to, based on the memory state of the neighboring aggressor memory cell being in the low substate, refine the initial error correction confidence value, the vector of which indicates a high confidence of a programmed state, by maintaining the initial error correction confidence value at a same confidence level.

10. The memory device of claim 1, wherein the memory controller is configured to, based on the memory state of the neighboring aggressor memory cell being in the high substate, refine the initial error correction confidence value, the vector of which indicates a high confidence of a programmed state, by adjusting the initial error correction confidence value to a lower confidence level, and
wherein the memory controller is configured to, based on the memory state of the neighboring aggressor memory cell being in the low substate, refine the initial error correction confidence value, the vector of which indicates a high confidence of an erased state, by adjusting the initial error correction confidence value to a lower confidence level.

11. The memory device of claim 1, wherein the memory controller is configured to, based on the memory state of the neighboring aggressor memory cell being in the low substate, refine the initial error correction confidence value, the vector of which indicates a low confidence of an erased state, by adjusting the initial error correction confidence value to a lower confidence level, and
wherein the memory controller is configured to, based on the memory state of the neighboring aggressor memory cell being in the high substate, refine the initial error correction confidence value, the vector of which indicates a low confidence of a programmed state, by adjusting the initial error correction confidence value to a lower confidence level,
wherein the memory controller is configured to, based on the memory state of the neighboring aggressor memory cell being in the high substate, refine the initial error correction confidence value, the vector of which indicates a high confidence of the erased state, by adjusting the initial error correction confidence value to a higher confidence level or maintaining the initial error correction confidence value at a same confidence level, and
wherein the memory controller is configured to, based on the memory state of the neighboring aggressor memory cell being in the low substate, refine the initial error correction confidence value, the vector of which indicates a high confidence of the programmed state, by adjusting the initial error correction confidence value to a higher confidence level or maintaining the initial error correction confidence value at a same confidence level.

12. The memory device of claim 11, wherein the memory controller is configured to, based on the memory state of the neighboring aggressor memory cell being in the low substate, refine the initial error correction confidence value, the vector of which indicates the low confidence of the programmed state, by adjusting the initial error correction confidence value to a higher confidence level, and
wherein the memory controller is configured to, based on the memory state of the neighboring aggressor memory cell being in the high substate, refine the initial error correction confidence value, the vector of which indicates the low confidence of the erased state, by adjusting the initial error correction confidence value to a higher confidence level.

13. The memory device of claim 1, further comprising:
an error correction code (ECC) decoder configured to receive the refined error correction confidence value, and determine a memory value of the victim memory cell based on the refined error correction confidence value.

14. The memory device of claim 1, wherein the victim memory cell is a single-bit memory cell.

15. The memory device of claim 1, wherein the victim memory cell is a multi-bit memory cell.

16. A memory system, comprising:
a memory comprising a memory cell array arranged according to a plurality of word lines and a plurality of bit lines; and
a memory controller configured to manage corrective read operations of the memory, wherein the memory controller is configured to:
perform a hard read on a victim memory cell based on a hard read threshold to estimate a memory state of the victim memory cell,
perform one or more soft reads on the victim memory cell based on one or more soft read thresholds to generate soft information for the victim memory cell,
calculate an initial log likelihood ratio (LLR) value of the victim memory cell based on the hard read performed on the victim memory cell and the soft information,
perform a hard read on a neighboring aggressor memory cell to determine a memory state of the neighboring aggressor memory cell, the memory state of the neighboring aggressor memory cell being in a high substate or a low substate, and
refine the initial LLR value of the victim memory cell, based on the hard read on the neighboring aggressor memory cell and based on an LLR value bucket of the initial LLR value, to generate a refined LLR value of the victim memory cell,
wherein the high substate is a high-voltage state corresponding to a programmed state of the neighboring aggressor memory cell, and wherein the low substate is a low-voltage state corresponding to an erased state of the neighboring aggressor memory cell.

17. The memory system of claim 16, wherein the victim memory cell and the neighboring aggressor memory cell are arranged on adjacent word lines of the memory cell array, and
wherein the victim memory cell and the neighboring aggressor memory cell are adjacent memory cells.

18. The memory system of claim 16, further comprising:
an error correction code (ECC) decoder configured to receive the refined LLR value, and correct a memory value of the victim memory cell based on the refined LLR value.

19. The memory system of claim 16, wherein the memory controller is configured to, based on the memory state of the neighboring aggressor memory cell being in the low substate, refine the initial LLR value, the LLR value bucket of which indicates a low confidence of an erased state, by adjusting the initial LLR value to a lower confidence level, and
wherein the memory controller is configured to, based on the memory state of the neighboring aggressor memory cell being in the high substate, refine the initial LLR value, the LLR value bucket of which indicates a low confidence of a programmed state, by adjusting the initial LLR value to a lower confidence level.

20. The memory system of claim 19, wherein the memory controller is configured to, based on the memory state of the neighboring aggressor memory cell being in the high substate, refine the initial LLR value, the LLR value bucket of which indicates a high confidence of the erased state, by adjusting the initial LLR value to a higher confidence level or maintaining the initial LLR value at a same confidence level, and
wherein the memory controller is configured to, based on the memory state of the neighboring aggressor memory cell being in the low substate, refine the initial LLR value, the LLR value bucket of which indicates a high confidence of the programmed state, by adjusting the initial LLR value to a higher confidence level or maintaining the initial LLR value at a same confidence level.

21. The memory system of claim 16, wherein, in the high substate, a read voltage value of the neighboring aggressor memory cell is greater than the hard read threshold, and
wherein, in the low substate, the read voltage value of the neighboring aggressor memory cell is less than the hard read threshold.

22. A method of performing a corrective read on a victim memory cell, the method comprising:
performing, by a memory controller, a hard read on the victim memory cell based on a hard read threshold to estimate a memory state of the victim memory cell;
performing, by the memory controller, one or more soft reads on the victim memory cell based on one or more soft read thresholds to generate soft information for the victim memory cell;
calculating, by the memory controller, an initial error correction confidence value of the victim memory cell based on the hard read performed on the victim memory cell and the soft information;
performing, by the memory controller, a hard read on a neighboring aggressor memory cell to determine a memory state of the neighboring aggressor memory cell, the memory state of the neighboring aggressor memory cell being in a high substate or a low substate; and
refining, by the memory controller, the initial error correction confidence value of the victim memory cell, based on the hard read on the neighboring aggressor memory cell and based on a vector of the initial error correction confidence value, to generate a refined error correction confidence value of the victim memory cell.

23. The method of claim 22, further comprising:
selectively modifying, by the memory controller, a log likelihood ratio (LLR) value of the victim memory cell based on the refined error correction confidence value.

24. The method of claim 22, further comprising:
bucketizing, by the memory controller, one or more bits of the victim memory cell into different confidence levels based on a substate of the neighboring aggressor memory cell.

25. The method of claim 22, further comprising:
analyzing, by the memory controller, shifts in a read voltage distribution of the victim memory cell influenced by electric fields from the neighboring aggressor memory cell.
